(19) United States
(12) Patent Application Publication
(10) Pub. No.: US 2012/0069530 A1
(43) Pub. Date: Mar. 22, 2012

(54) SEMICONDUCTOR DEVICE AND METHOD OF MANUFACTURING THE SAME

(75) Inventors: Satoshi Inoue, Yokohama-shi (JP); Kazushige Kanda, Kawasaki-shi (JP); Yuui Shimizu, Yokohama-shi (JP)

(73) Assignee: Kabushiki Kaisha Toshiba, Tokyo (JP)

(21) Appl. No.: 13/234,426

(22) Filed: Sep. 16, 2011

(30) Foreign Application Priority Data
Sep. 17, 2010 (JP) 2010-209998

(51) Int. Cl. H05K 7/00; H01L 21/66

(52) U.S. Cl. 361/735; 438/10; 257/E21.531

(57) ABSTRACT

According to one embodiment, a semiconductor device includes a stacked chip includes semiconductor chips which are stacked, the semiconductor chips comprises semiconductor substrates and through electrodes formed in the semiconductor substrates, respectively, the through electrodes being electrically connected, and deactivating circuits provided in the semiconductor chips, respectively, and configured to deactivate a failed semiconductor chip.

### CROSS-REFERENCE TO RELATED APPLICATIONS

This application is based upon and claims the benefit of priority from prior Japanese Patent Application No. 2010-209998, filed Sep. 17, 2010, the entire contents of which are incorporated herein by reference.

### FIELD

Embodiments described herein relate generally to a semiconductor device and a method of manufacturing the same.

### BACKGROUND

As one type of semiconductor memory device, for example, a NAND flash memory is known. The NAND flash memory is used in various fields, such as portable information terminals, memory cards, etc.

On the other hand, as a technique to realize a high integration and a large capacity of a system LSI, for example, a multi chip package (MCP) is used. By configuring the semiconductor memory device such as the NAND flash memory using the MCP, high integration and high capacity become possible.

### BRIEF DESCRIPTION OF THE DRAWINGS

FIG. 1 is a cross sectional diagram showing a structure of a multi chip package;

FIG. 2 is a plan diagram showing a configuration of the multi chip package;

FIG. 3 is a cross sectional diagram showing a configuration of semiconductor chips;

FIG. 4 is a block diagram showing a configuration of a NAND flash memory;

FIG. 5 is a circuit diagram showing an example of a deactivating circuit;

FIG. 6 is a flow chart of a method of manufacturing the multi chip package;

FIG. 7 is a perspective diagram showing a manufacturing process of the multi chip package;

FIG. 8 is a cross sectional diagram showing the manufacturing process of the multi chip package;

FIG. 9 is a cross sectional diagram showing the manufacturing process of the multi chip package;

FIG. 10 is a cross sectional diagram showing the manufacturing process of the multi chip package;

FIG. 11 is a cross sectional diagram showing the manufacturing process of the multi chip package;

FIG. 12 is a perspective diagram showing the manufacturing process of the multi chip package; and

FIG. 13 is a perspective diagram showing the manufacturing process of the multi chip package.

### DETAILED DESCRIPTION

In general, according to one embodiment, there is provided a semiconductor device comprising:

a stacked chip comprising semiconductor chips which are stacked, the semiconductor chips comprises semiconductor substrates and through electrodes formed in the semiconductor substrates, respectively, the through electrodes being electrically connected; and

deactivating circuits provided in the semiconductor chips, respectively, and configured to deactivate a failed semiconductor chip.

The embodiments will be described hereinafter with reference to the accompanying drawings. In the description which follows, the same or functionally equivalent elements are denoted by the same reference numerals, to thereby simplify the description.

### [1] Structure of Multi Chip Package (MCP) 10

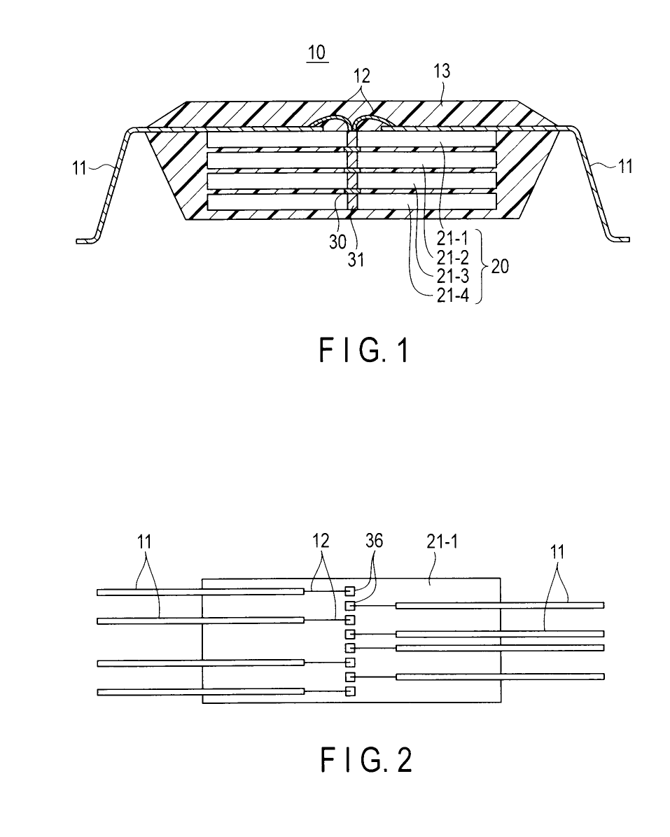

FIG. 1 is a cross sectional diagram showing a structure of the multi chip package 10 of the present embodiment. FIG. 2 is a plan diagram showing a configuration of the multi chip package 10.

The multi chip package 10 comprises a stacked chip (multi chip) 20 in which a plurality of semiconductor chips 21 are stacked in a vertical direction. Note that, although a stacked chip 20 in which four semiconductor chips 21-1 to 21-4 are stacked is shown in FIG. 1 as an example, there is no particular limit as to the number of semiconductor chips 21.

The stacked semiconductor chips 21-1 to 21-4 are electrically connected by through electrodes (through via plugs) 31 and bumps 30 as will be described later. The stacked chip 20 is electrically connected to one ends of a plurality of bonding wires 12 via a plurality of pads 36. The other ends of the bonding wires 12 are electrically connected to a plurality of input/output pins 11. The stacked chip 20, a part of the input/output pins 11, and the bonding wires 12 are packaged by a packaging material 13 formed, for example, of molded resin.

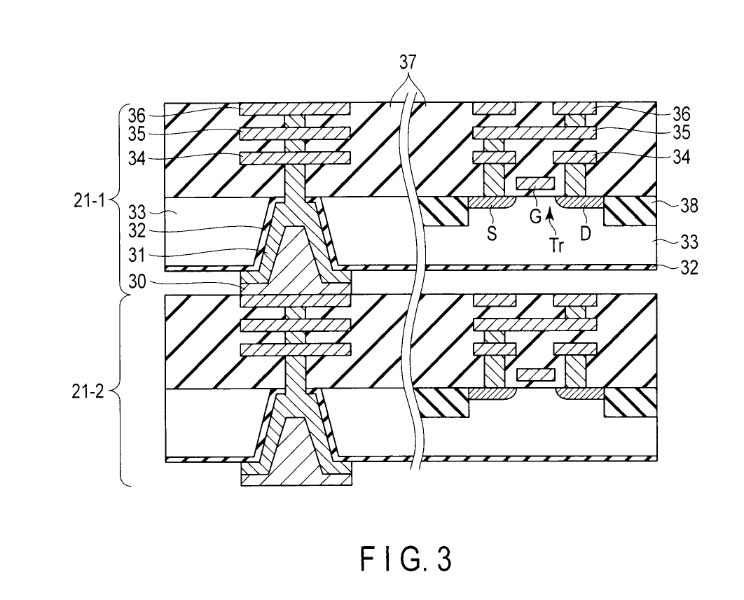

FIG. 3 is a cross sectional diagram showing a configuration of the semiconductor chip 21. The semiconductor chip 21 comprises a semiconductor substrate 33 formed, for example, of a silicon (Si) substrate, semiconductor elements formed on the semiconductor substrate 33, wiring layers, etc. In the semiconductor element, a MOS (Metal Oxide Semiconductor) transistor, a diode, a logic circuit, a memory element, etc. are included. In FIG. 3, a MOS transistor Tr is shown as an example of the semiconductor element.

In the semiconductor substrate 33, an element isolating insulation layer 38 that electrically isolates adjacent semiconductor elements is formed. The MOS transistor Tr is formed in an element region (active region), in a front surface region of the semiconductor substrate 33, where the element isolating insulation layer 38 is not formed. The MOS transistor Tr comprises a source region S and a drain region D that are separated from each other in the semiconductor substrate 33, and a gate electrode G formed on the semiconductor substrate 33 between the source region S and the drain region D with a gate insulating film being intervened.

In the semiconductor substrate 33, a through electrode (through via plug) 31 penetrating therethrough is provided. An insulating film 32 is formed between the through electrode 31 and the semiconductor substrate 33. On the through electrode 31, a first level wiring layer 34 is provided. Above the first level wiring layer 34, a second level wiring layer 35 is provided. The first level wiring layer 34 and the second level wiring layer 35 are electrically connected by a via plug. Above the second level wiring layer 35, a pad 36 configured as a third level wiring layer is provided. The second level wiring layer 35 and the pad 36 are electrically connected by a via plug. Note that there is no particular limit to the number of stacked layers in the wiring layer; it may be three layers or more, or may be less than three layers.

The through electrode 31 of the semiconductor chip 21-1 and the pad 36 of the semiconductor chip 21-2 are electrically connected by a bump (protruding electrode) 30. The bump 30 is formed, for example, of a solder ball. An interlayer insulating layer 37 is present between the semiconductor substrate 33 and the pad 36. In the stacked chip 20 configured as above, it is possible to electrically connect the semiconductor chips 21 with the minimum distance by the through electrodes 31 formed by penetrating through the semiconductor substrates 33. As wirings to be connected using the through electrodes 31, such may be a power line, or a signal line.

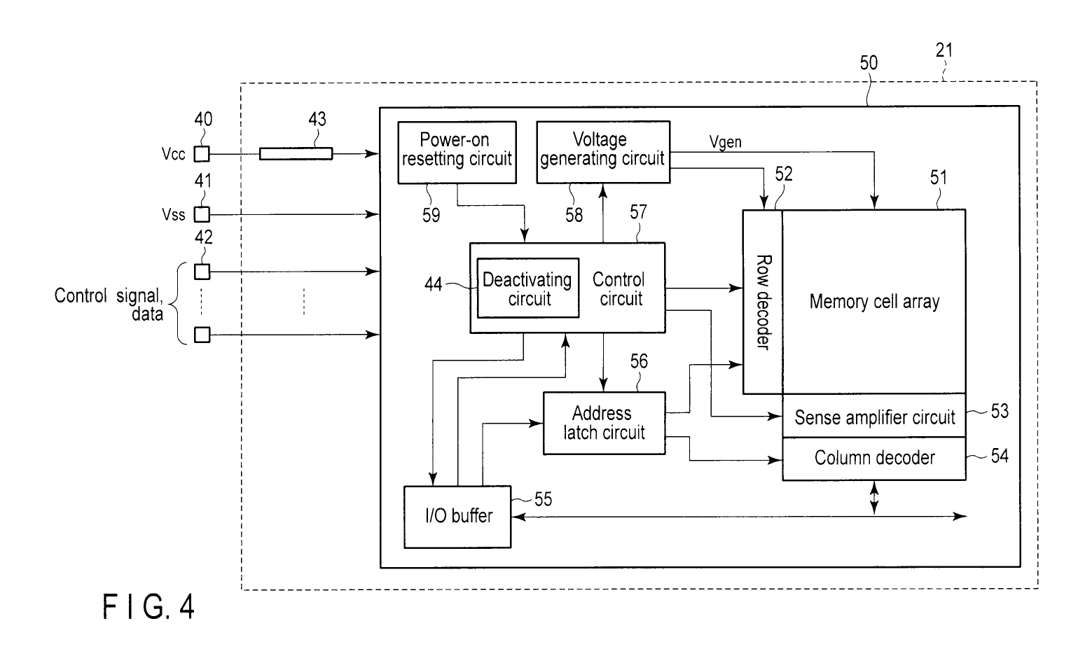

Next, a circuit configuration embedded in the semiconductor chip 21 will be explained. In the present embodiment, as a circuit to be embedded in the semiconductor chip 21, an explanation will be given with a NAND flash memory as an example. FIG. 4 is a block diagram showing a configuration of the NAND flash memory.

The semiconductor chip 21 comprises a pad 40 to which a power voltage Vcc is applied, a pad 41 to which a ground voltage Vss is applied, and a plurality of pads 42 to which various control signals are input and from which data are output. The pad 40 is connected to a circuit unit 50 via a cutting wiring 43. The cutting wiring 43 will be described later. The pads 41 and 42 are connected to the circuit unit 50.

The circuit unit 50 comprises various circuits 51 to 59 that configure the NAND flash memory. A memory cell array 51 is configured, for example, by a plurality of floating gate type memory cells being arranged in a matrix. A row decoder (including a word line driving circuit) 52 drives word lines and a select gate line provided in the memory cell array 51. A sense amplifier circuit 53 comprises a sense amplifier, for example, for one page and a data latch circuit, and configures a page buffer that performs data writing and data reading in page units on the memory cell array 51.

Read data for one page read by the sense amplifier circuit 53 is selected by a column decoder (column gate) 54, and transferred to an I/O buffer 55. The read data transferred to the I/O buffer 55 is output outside from I/O terminals included in the pads 42. The write data input to the I/O terminal is selected by the column decoder 54, and is loaded to the sense amplifier circuit 53. The write data for one page is loaded to the sense amplifier circuit 53, and this is latched until a writing cycle is completed.

An address signal is input to the I/O buffer 55 via a pad 42, and thereafter is latched in an address latch circuit 56. The address signal latched in the address latch circuit 56 is transferred to the row decoder 52 and the column decoder 54.

A control circuit 57 generates respective internal timing signals for timing control of data reading, writing and erasing based on control signals such as a chip enable signal/CE, a write enable signal/WE, a read enable signal/RE, an address latch enable signal ALE, a command latch enable signal CLE, etc. The above signal “/” denotes being low active. The control circuit 57 performs a sequence control for the data writing and erasing and an operational control for the data reading based on the internal timing signals. Further, the control circuit 57 comprises a deactivating circuit 44. The deactivating circuit 44 is a circuit for deactivating the semiconductor chip 21 onto which it is embedded.

A voltage generating circuit 58 is controlled by the control circuit 57, and generates various high voltages Vgen used for the data writing and erasing. A power-on resetting circuit 59 resets circuits in the semiconductor chip 21 when power is turned on so as to prevent erroneous operations of the circuits in the semiconductor chip 21. In order to do so, the power-on resetting circuit 59 generates a reset signal/RST. The power-on resetting circuit 59 monitors the power voltage Vcc, and outputs the reset signal/RST of a low level pulse in a case where the power voltage Vcc comes to be equal to or higher than a threshold. The circuits in the semiconductor chip 21 are reset by the reset signal/RST.

Each of the semiconductor chips 21-1 to 21-4 is configured of the NAND flash memory shown in FIG. 4. That is, in the present embodiment, a case in which the semiconductor chips 21-1 to 21-4 configuring the stacked chip 20 comprise an identical circuit configuration is explained as an example. However, such configuration is not restrictive, and the stacked chip 20 as a whole may configure one NAND flash memory whereby the semiconductor chips 21-2 to 21-4 may serve as slave chips and the semiconductor chip 21-1 may serve as a master chip. In such a configuration, primarily memory cell arrays are embedded in the slave chips, and a control circuit that controls the memory cell arrays and a power circuit are embedded in the master chip.

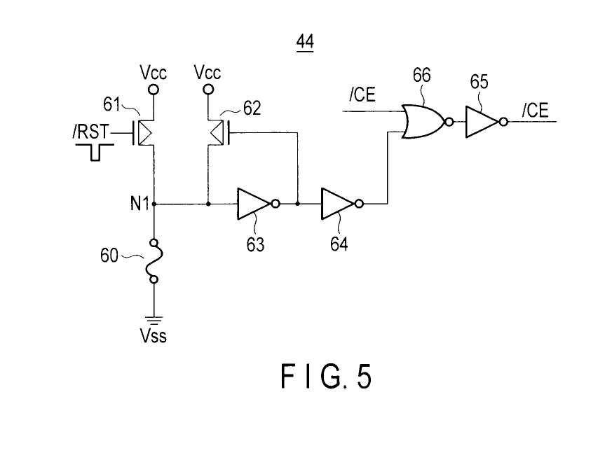

Next, a configuration of the deactivating circuit 44 will be explained. In the present embodiment, each of the semiconductor chips 21 comprises the deactivating circuit 44 shown in FIG. 4. FIG. 5 is a circuit diagram showing an example of the deactivating circuit 44.

The deactivating circuit 44 comprises a fuse 60, P-channel MOS transistors (PMOS transistors) 61 and 62, inverter circuits 63 to 65, and a NOR gate 66.

One terminal of the fuse 60 is connected to a node N1, and the other terminal is grounded. As the fuse 60, a laser fuse that can be cut off by laser, or an electric fuse (e-fuse) that can be electrically cut off is used.

A source of the PMOS transistor 61 is connected to the power voltage terminal Vcc, a drain of the PMOS transistor 61 is connected to the node N1, and the reset signal/RST is input from the power-on resetting circuit 59 to a gate of the PMOS transistor 61. A source of the PMOS transistor 62 is connected to the power voltage terminal Vcc, and a drain of the PMOS transistor 62 is connected to the node N1.

An input terminal of the inverter circuit 63 is connected to the node N1, and an output terminal of the inverter circuit 63 is connected to the gate of the PMOS transistor 62 and the input terminal of the inverter circuit 64. The output terminal of the inverter circuit 64 is connected to a first input terminal of the NOR gate 66.

The chip enable signal/CE is input to a second input terminal of the NOR gate 66 from outside, and an output terminal of the NOR gate 66 is connected to an input terminal of the inverter circuit 65. The inverter circuit 65 outputs a new chip enable signal/CE, and this chip enable signal/CE is sent to the control circuit 57.

### [2] Manufacture Method

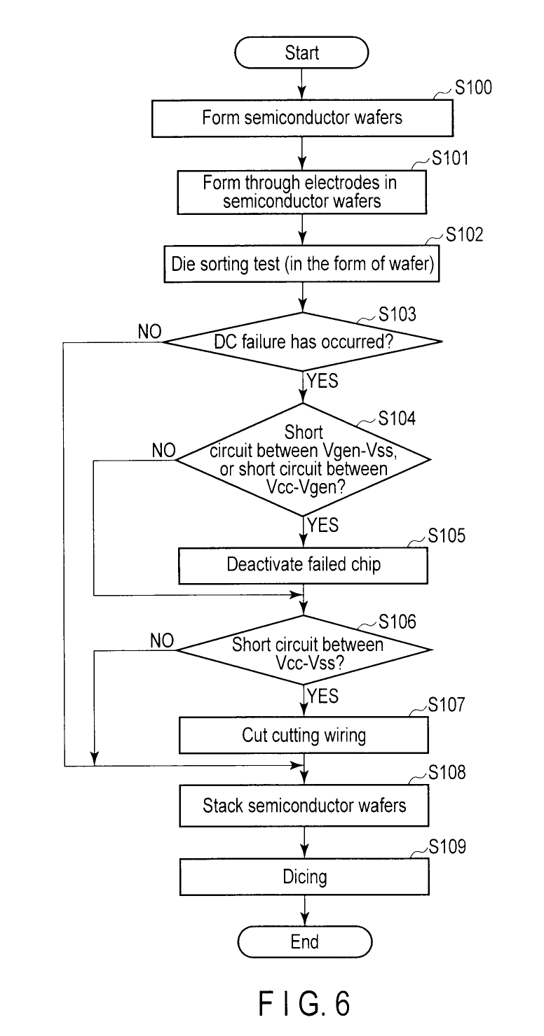

Next, a method of manufacturing the multi chip package 10 will be explained. FIG. 6 is a flow chart showing the method of manufacturing the multi chip package 10.

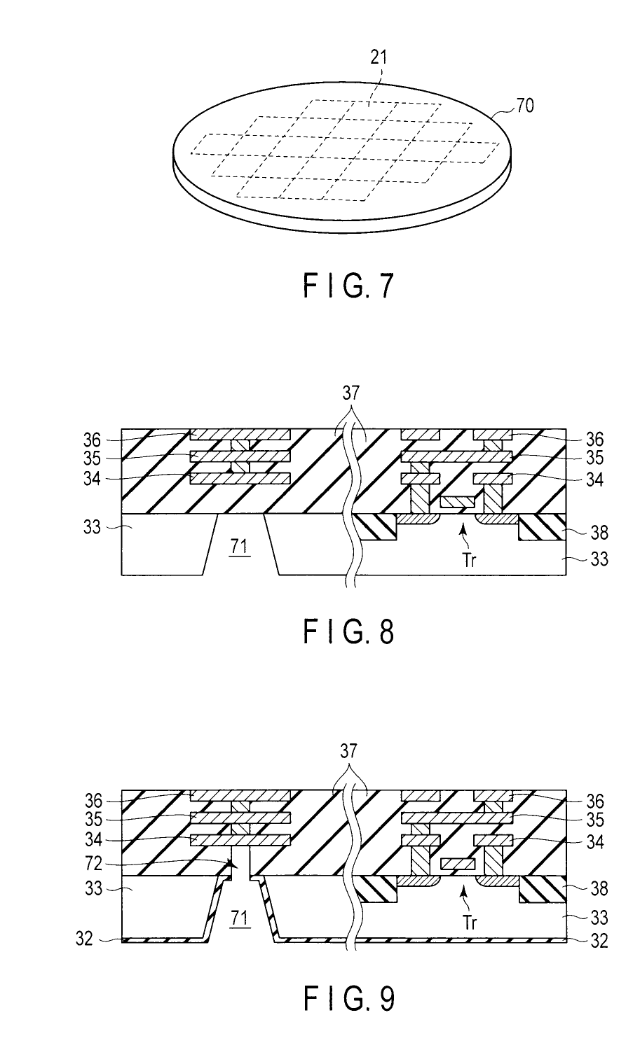

First, as shown in FIG. 7, a semiconductor wafer 70 comprising a plurality of semiconductor chips 21 is formed. Further, a plurality of the semiconductor wafers 70 shown in FIG. 7 are formed (step S100).

Subsequently, the through electrodes 31 are formed in each of the semiconductor wafers 70 (step S101). Specifically, as shown in FIG. 8, by using a photolithography technique, a resist pattern in which an opening corresponding to a plane shape of a through hole 71 is formed on a back surface of the semiconductor substrate 33. Further, by performing a dry etching on the semiconductor substrate 33 with this resist pattern as a mask, the through hole 71 is formed in the semiconductor substrate 33. Thereafter, by an ashing process, the resist pattern is removed.

Subsequently, as shown in FIG. 9, for example, by a CVD (Chemical Vapor Deposition) method, the insulating film 32 is formed on the back surface of the semiconductor substrate 33 such that a side wall of the through hole 71 is covered. As the insulating film 32, for example, silicon oxide is used. Subsequently, by using the photolithography technique and the dry etching process, an opening 72 reaching the first level wiring layer 34 is formed in the insulating film 32 and the interlayer insulating layer 37.

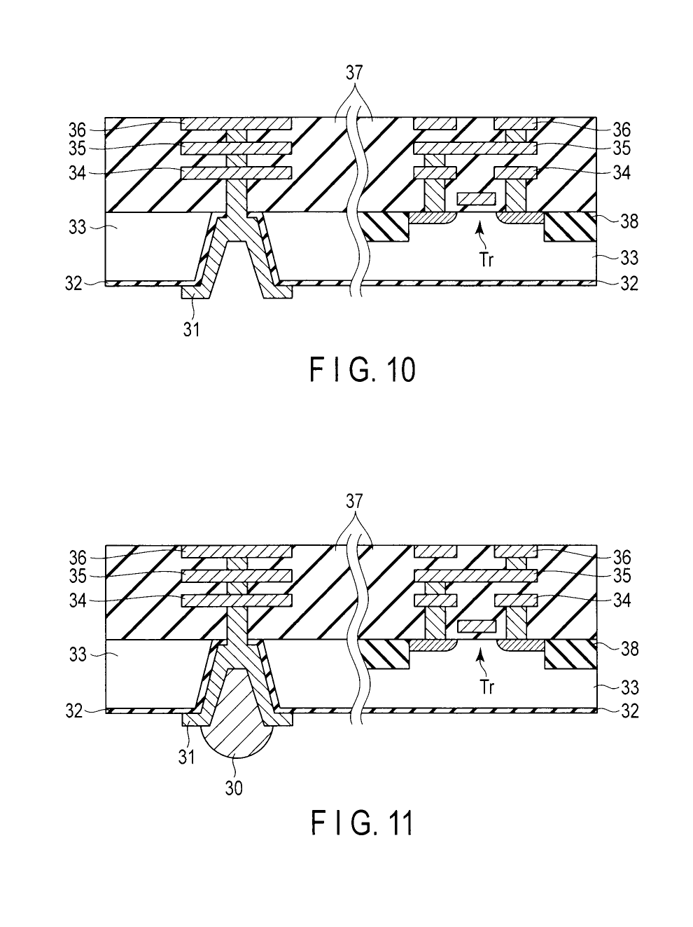

Subsequently, as shown in FIG. 10, for example, by a Cu plating, the opening 72 is filled, and the through electrode 31 covering the sidewall of the through hole 71 is formed. Subsequently, as shown in FIG. 11, for example, by using a solder ball, the bump 30 that makes contact with the through electrode 31 and protrudes from the semiconductor substrate 33 is formed. Accordingly, the through electrode 31 is formed in the semiconductor substrate 33.

Subsequently, a die sorting test is performed on the semiconductor chips 21 in the form of a wafer (step S102). The die sorting test is a selection of failed chips in the form of the wafer, and includes an electrical property testing process. In the die sorting test of the semiconductor chips 21 in the form of the wafer, a semiconductor chip in which a DC failure has occurred is identified (step S103). The DC failure denotes a failure caused by the power lines, and includes a failure in which a short circuit has occurred between the power lines and a failure in which a part of the power lines has become open. In the semiconductor chip 21, a power line Vcc for sending the power voltage Vcc applied from outside of the chip to circuits in the chip, a power line (ground line) Vss for sending the ground voltage Vss applied from outside of the chip to the circuits in the chip, and a power line Vgen for sending the power voltage Vgen generated inside the chip to the circuits in the chip are provided.

Based on a result of the die sorting test, the DC failure is categorized into three types: (1) the short circuit between the power line Vgen and the power line Vss, (2) the short circuit between the power line Vcc and the power line Vgen and (3) the short circuit between the power line Vcc and the power line Vss. Due to having the through electrodes, there lies a problem that one DC failed chip affects all of the other stacked chips. Therefore, in the semiconductor chip in which the DC failure (1) or the DC failure (2) has occurred, the semiconductor chip is deactivated. According to this, even in a stacked chip including the semiconductor chip in which the DC failure has occurred, the failed chip affecting other satisfactory semiconductor chips can be avoided. On the other hand, in a semiconductor chip in which the DC failure (3) has occurred, the power line Vcc or the power line Vss of this semiconductor chip is cut in the vicinity of the pad. According to this, even in the stacked chip including the semiconductor chip in which the DC failure has occurred, the failed chip affecting the other satisfactory semiconductor chips can be avoided.

Hereinbelow, a specific method of dealing with the DC failure will be explained.

(1) The Short Circuit Between the Power Line Vgen and the Power Line Vss or (2) the Short Circuit Between the Power Line Vcc and the Power Line Vgen

In the case where the DC failure (1) or the DC failure (2) has occurred (step S104), the semiconductor chip becomes inoperable. Thus, this failed chip is deactivated (step S105). According to this, the chip enable signal/CE input to the failed chip is caused to constantly be at a high level (deactivated state) by the deactivating circuit 44.

That is, in the deactivating circuit 44 embedded in the failed chip, the fuse 60 shown in FIG. 5 is cut. In a state of the fuse 60 having been cut, when the power-on resetting signal/RST is at a low level on turning on the power, the node N1 comes to be at a high level. The node N1 is connected to the NOR gate 66 via the two inverter circuits 63, 64. According to this, the deactivating circuit 44 constantly outputs a high-level chip enable signal/CE regardless of the logic of the chip enable signal/CE input from the outside. Due to this, the aforementioned failed chip is never activated.

On the other hand, in a case where the fuse 60 is not cut, the deactivating circuit 44 outputs the chip enable signal/CE input from the outside in its original logic state. Accordingly, the Enable/Disable of the satisfactory semiconductor chip can be controlled by the chip enable signal/CE input from the outside.

(3) The Short Circuit Between the Power Line Vcc and the Power Line Vss

If the external power line, to which the power voltage from the outside of the semiconductor chip is applied, and the ground line are short circuited, the stacked chip cannot be saved by the aforementioned techniques due to a large current flowing in the entirety of the semiconductor chip. Needless to say, in the case where the external power lines and the ground lines are electrically connected by the through electrodes, the large current flows in the entirety of the stacked chip.

In the case of the DC failure (3), it is necessary to physically cut the short circuited section using a laser, etc. At such an occasion, if the short circuited sections are each cut independently, a throughput is poor and a cost is increased. Therefore, in the present embodiment, as shown in FIG. 4, the cutting wiring 43 is arranged beforehand in the vicinity of the pad 40, i.e. between the pad 40 and the circuit unit 50. The cutting wiring 43 is configured preferably of a material that easily melts by a heat of the laser and is formed with a larger diameter than that of other wirings, and other wirings are not arranged in its periphery so that the cutting is made easier. By physically cutting this cutting wire 43, the failed chip can be deactivated (step S107).

Note that, in the present embodiment, although the cutting wiring 43 is attached on the power line Vcc, the cutting wiring 43 may be attached on the power line Vss. Even in such an example, by cutting the cutting wiring 43, the short circuit between the power line Vcc and the power line Vss can be prevented.

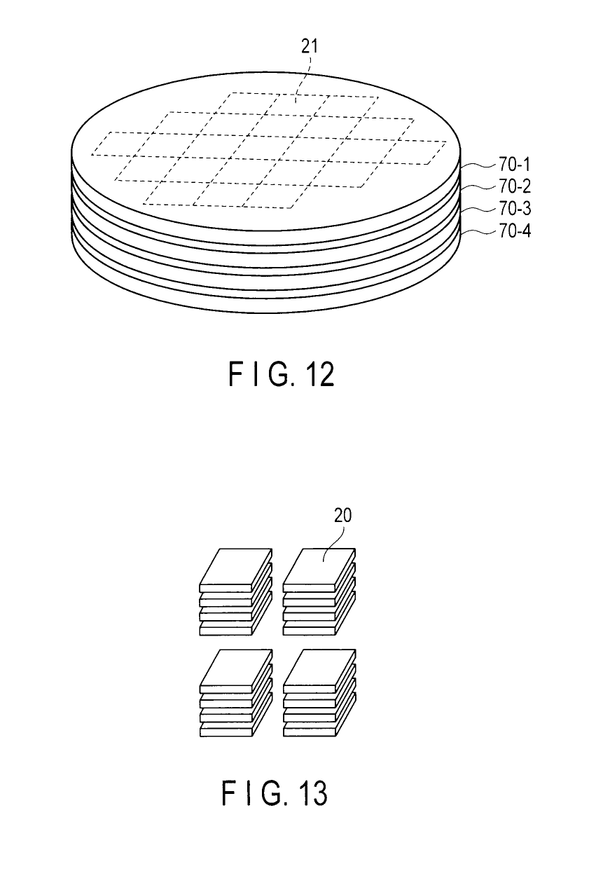

Next, as shown in FIG. 12, the semiconductor wafers 70-1 to 70-4 are stacked such that the bump of an upper semiconductor wafer is connected to the pad of a lower semiconductor wafer (step S108).

Subsequently, as shown in FIG. 13, the stacked wafer is diced (step S109). Accordingly, a plurality of stacked chips 20 are formed. Thereafter, by packaging the stacked chip 20, the manufacture of the multi chip package 10 is completed.

Note that, in the above two techniques, the multi chip package 10 whose failed chip has been deactivated may compensate for the lost memory capacity by further stacking the same number of new and satisfactory semiconductor as failed chips.

### [3] Effects

As described in detail above, in the present embodiment, in manufacturing the multi-chip package 10, the die sorting test is performed on the plurality of semiconductor wafers 70, and the DC failure is categorized into three types: (1) the short circuit between the power line Vgen and the power line Vss, (2) the short circuit between the power line Vcc and the power line Vgen and (3) the short circuit between the power line Vcc and the power line Vss based on the result of the die sorting test. Then, for the failed chip in which the DC failure (1) or the DC failure (2) has occurred, the failed chip is deactivated by the deactivating circuit 44. In the case where the DC failure (3) has occurred, the failed chip is deactivated by physically cutting the cutting wiring 43 provided in the vicinity of the pad 40. Thereafter, the plurality of semiconductor wafers 70 are stacked, and the stacked chips 20 are formed by dicing this stacked wafer. Further, the stacked chips 20 are electrically connected at the minimum distance using the through electrodes 31.

According to the present embodiment, in the multi chip package 10 including the stacked chips 20 electrically connected using the through electrodes 31, the failed chip in which the DC failure has occurred can be deactivated. According to this, the failed chip affecting the other chips can be avoided.

Further, even in the case where a short circuit occurs between the external power Vcc and Vss, the power line of the failed chip can be cut off from other chips. Due to this, even in the case of the external power Vcc and Vss being electrically connected among the semiconductor chips using the through electrodes 31, a failed element can be saved as a satisfactory element.

Further, in the multi chip packaging, when the semiconductor chips are stacked after the semiconductor wafer is diced, a manufacturing process is complicated, and a manufacturing cost is increased. However, in the present embodiment, since the semiconductor chips are stacked in the form of the semiconductor wafer, the manufacturing process is simplified, and the manufacturing cost is reduced.

Note that, in the present embodiment, the NAND flash memory is explained as an example of the circuit to be embedded in the multi chip package 10. However, the present embodiment is not limited to this, and it goes without saying that the present embodiment can be adapted to semiconductor memories other than the NAND flash memory.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a stacked chip comprising semiconductor chips which are stacked, the semiconductor chips comprises semiconductor substrates and through electrodes formed in the semiconductor substrates, respectively, the through electrodes being electrically connected; and
deactivating circuits provided in the semiconductor chips, respectively, and configured to deactivate a failed semiconductor chip.

2. The device of claim 1, wherein
each of the semiconductor chips comprises a first power line to which an external power is applied, a second power line to which an internal power generated in the semiconductor chip is applied and a ground line to which a ground voltage is applied,
first power lines included in the semiconductor chips are electrically connected by through electrodes,
second power lines included in the semiconductor chips are electrically connected by through electrodes, and
ground lines included in the semiconductor chips are electrically connected by through electrodes.

3. The device of claim 2, wherein
each of the deactivating circuits constantly deactivates a chip enable signal in one of cases where a short circuit occurs between a second power line and a ground line, and where a short circuit occurs between a first power line and a second power line.

4. The device of claim 3, wherein the deactivating circuit comprises a fuse, and controls the chip enable signal in accordance with a state of the fuse.

5. The device of claim 3, wherein the chip enable signal controls an activation and a deactivation of the semiconductor chip.

6. The device of claim 3, wherein the semiconductor chip receives the chip enable signal from outside.

7. The device of claim 2, wherein the semiconductor chip comprises a voltage generating circuit that generates the internal power using the external power.

8. The device of claim 2, wherein
the semiconductor chip comprises one of a wiring provided between a pad and a first power line or a wiring between the pad and a ground line, and
the wiring is cut in a case where a short circuit has occurred between the first power line and the ground power line.

9. The device of claim 8, wherein the wiring is made of a material that melts by heat generated from a laser.

10. The device of claim 1, wherein the semiconductor chip is a semiconductor memory.

11. A method of manufacturing a semiconductor device, the method comprising:
preparing wafers comprising semiconductor substrates and through electrodes formed in the semiconductor substrates, respectively;
testing electrical properties of semiconductor chips included in each of the wafers;
deactivating a failed semiconductor chip based on a result of the testing;
stacking the wafers such that the through electrodes are electrically connected; and
dividing the stacked wafers into stacked chips.

12. The method of claim 11, wherein
each of the semiconductor chips comprises a first power line to which an external power is applied, a second power line to which an internal power generated in the semiconductor chip is applied and a ground line to which a ground voltage is applied,
first power lines included in the semiconductor chips are electrically connected by through electrodes,
second power lines included in the semiconductor chips are electrically connected by through electrodes, and
ground lines included in the semiconductor chips are electrically connected by through electrodes.

13. The method of claim 12, wherein the deactivating comprises constantly deactivating a chip enable signal in one of cases where a short circuit occurs between a second power line and a ground line, and where a short circuit occurs between a first power line and a second power line.

14. The method of claim 12, wherein the semiconductor chip comprises a voltage generating circuit that generates the internal power using the external power.

15. The method of claim 12, wherein the deactivating comprises cutting a first power line or a ground line from a pad in a case where a short circuit has occurred between the first power line and the ground power line.

16. The device of claim 11, wherein the semiconductor chip is a semiconductor memory.
